(19) United States
(12) Patent Application Publication
(10) Pub. No.: US 2008/0101041 A1
(43) Pub. Date: May 1, 2008

(54) ELECTRONIC DEVICE HAVING WATER-REPELLENT STRUCTURE AND DRAINING STRUCTURE

(75) Inventors: Yung-Cheng Chang, Taoyuan (TW); His-An Liu, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan (TW)

(21) Appl. No.: 11/764,865

(22) Filed: Jun. 19, 2007

(30) Foreign Application Priority Data
Oct. 26, 2006 (TW) 095139614

(51) Int. Cl. H05K 7/00; H01S 4/00

(52) U.S. Cl. 361/728; 29/592.1

(57) ABSTRACT

An electronic device includes a housing, a water-repellent structure and a draining structure. The housing has at least a first air port. The water-repellent structure is connected to the housing and includes at least one draining port. The water-repellent structure and the housing cooperatively define a water-repellent chamber. The draining structure is disposed in the water-repellent chamber for reducing the possibility of splashing the fluid into the water-repellent chamber and guiding the fluid which is splashed into the water-repellent chamber to be discharged out through the draining port.

### FIELD OF THE INVENTION

The present invention relates to an electronic device, and more particularly to an electronic device having a water-repellent structure and a draining structure.

### BACKGROUND OF THE INVENTION

With increasing integration of integrated circuits, electronic devices such as power adapters and power supply apparatuses are developed toward minimization. As the volume of the electronic device is decreased, the problem associated with heat dissipation becomes more serious. Take a power adapter for example. The conventional power adapter comprises an upper housing and a lower housing, which are made of plastic materials and cooperatively define a closed space for accommodating a printed circuit board. When the power adapter operates, the electronic components on the printed circuit board thereof may generate energy in the form of heat, which is readily accumulated in the closed space and usually difficult to dissipate away. If the power adapter fails to transfer enough heat to ambient air, the elevated operating temperature may result in damage of the electronic components, a breakdown of the whole power adapter or reduced power conversion efficiency.

Referring to FIG. 1, a schematic cross-sectional view of a conventional power adapter is illustrated. The power adapter 1 comprises an upper housing 11, a lower housing 12, a printed circuit board 13, a power input terminal (not shown) and a power output terminal 14. A closed space is defined between the upper housing 11 and the lower housing 12 for accommodating therein the printed circuit board 13. Many electronic components 131 are mounted on the printed circuit board 13. In order to remove most heat generated from the electronic components 131, several heat sinks 132 are attached on the printed circuit board 13. In addition, some electronic components 131 are coupled to the heat sinks 132 by screwing or riveting connection, thereby facilitating heat dissipation.

The heat dissipation mechanism of the power adapter 1 comprises conducting heat generated from the electronic components 131 to the heat sinks 132, radiating heat from the surfaces of the heat sinks 132 to the closed space of the power adapter 1, transferring heat from the closed space to the upper housing 11 and the lower housing 12 through air, and afterwards performing heat-exchange with the surrounding of the power adapter 1. Since the power adapter is developed toward minimization and designed to have higher power, the passive heat dissipation mechanism described above is not satisfactory.

For enhancing heat-dissipation efficiency, the heat generated from the internal electronic components of the power adapter 1 should be actively dissipated away the power adapter 1. In order to be applied to most operating statues and environments, the housing of the power adapter 1 should have additional openings such that the space defined by the housing is communicated with external ambient air. Under this circumstance, the power adapter 1 fails to be operated in humid surroundings or outdoors due to the poor waterproof properties. If the power adapter 1 having the active heat dissipation mechanism is used in the humid surroundings or outdoors, the electronic components may be damaged or short-circuited in case of contacting with water.

In views of the above-described disadvantages resulted from the prior art, the applicant keeps on carving unflaggingly to develop an electronic device with a water-repellent structure and a draining structure according to the present invention through wholehearted experience and research.

### SUMMARY OF THE INVENTION

It is an object of the present invention to provide an electronic device with a water-repellent structure and a draining structure for guiding the fluid splashed into the water-repellent chamber to be discharged out through draining ports, such that the electronic device may have an active heat dissipation mechanism and operated in humid surroundings or outdoors.

In accordance with an aspect of the present invention, there is provided an electronic device. The electronic device includes a housing, a water-repellent structure and a draining structure. The housing has at least a first air port. The water-repellent structure is connected to the housing and includes at least one draining port. The water-repellent structure and the housing cooperatively define a water-repellent chamber. The draining structure is disposed in the water-repellent chamber for preventing the fluid from being splashed into the water-repellent chamber and guiding the fluid which is splashed into the water-repellent chamber to be discharged out through the draining port.

In accordance with another aspect of the present invention, there is provided a process of fabricating an electronic device. The process comprises the steps of: providing a housing having at least one first air port; providing a water-repellent structure and a draining structure, wherein the water-repellent structure includes at least one draining port; and connecting the water-repellent structure with the housing to form a water-repellent chamber, and placing the draining structure in the water-repellent chamber, thereby preventing the fluid from being splashed into the water-repellent chamber and guiding the fluid which is splashed into the water-repellent chamber to be discharged out through the at least one draining port.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a conventional power adapter;

FIGS. 2(a) and 2(b) are schematic views of an electronic device with a water-repellent structure and a draining structure according to a first preferred embodiment of the present invention;

FIGS. 3(a) and 3(b) are schematic views of an electronic device with a water-repellent structure and a draining structure according to a second preferred embodiment of the present invention;

FIGS. 4(a) and 4(b) are schematic views of an electronic device with a water-repellent structure and a draining structure according to a third preferred embodiment of the present invention; and

FIGS. 5(a), 5(b) and 5(c) are schematic views of an electronic device with a water-repellent structure and a draining structure according to a fourth preferred embodiment of the present invention.

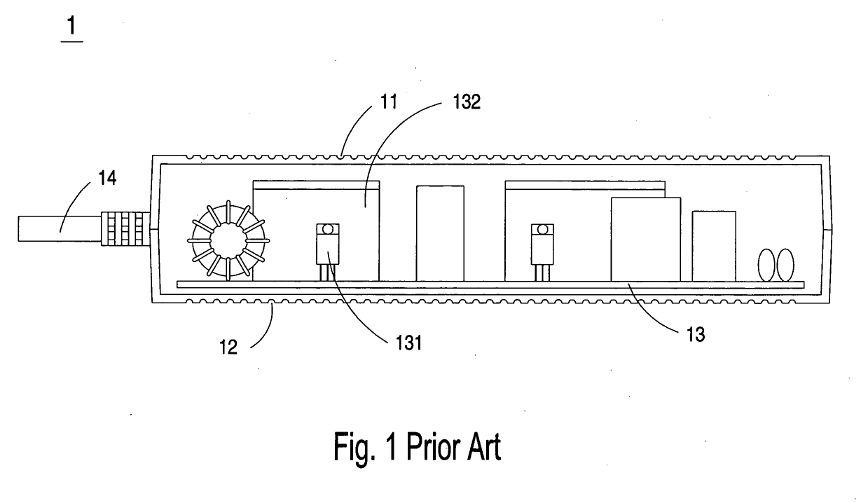

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

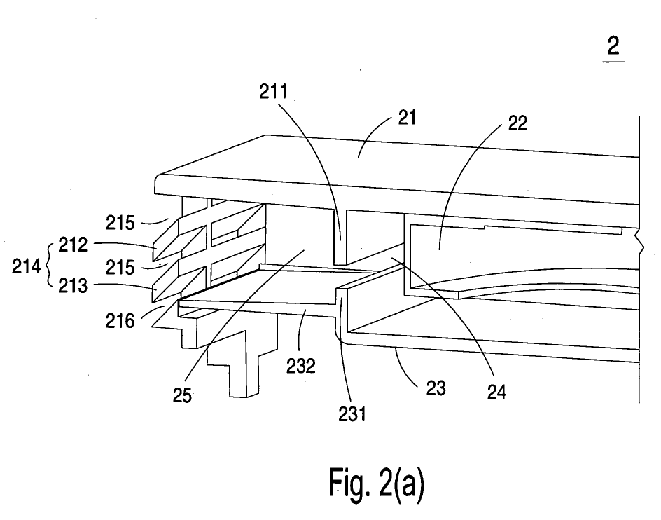

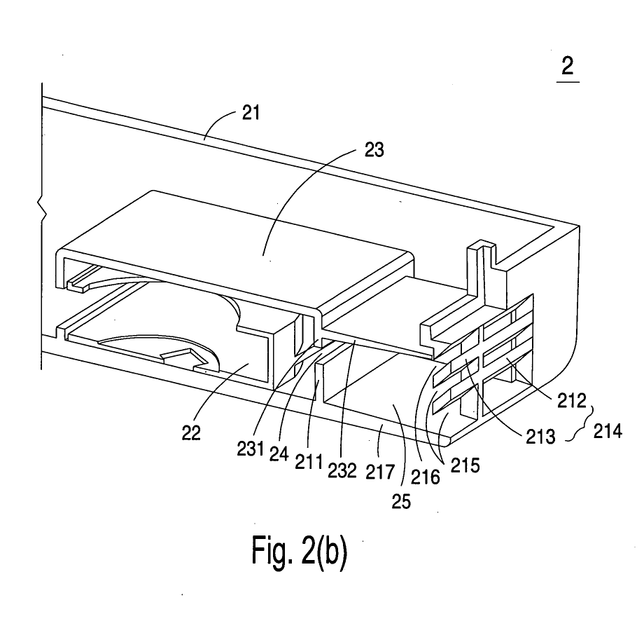

Referring to FIG. 2(a), a perspective view of an electronic device having a water-repellent structure and a draining structure according to a first preferred embodiment is schematically shown. As shown in FIG. 2(a), the electronic device 2 includes a housing 21, a fan receiving slot 22 and a sheltering member 23. The housing 21 includes a partition plate 211 and a water-repellent structure 214. The partition plate 211 is extended from an inner surface of the housing 21.

The fan receiving slot 22 is a receptacle for accommodating a heat-dissipating fan (not shown) therein. Alternatively, the location of the fan receiving slot 22 may be replaced with a fan body per se. The sheltering member 23 is responsible for partially sheltering the fan receiving slot 22 (or the fan body). The sheltering member 23 includes a protrusion plate 231 and a draining structure 232, which are integrally formed into one piece. The protrusion plate 231 is protruded from the sheltering member 23 facing to the inner surface of the housing 21 and is selectively aligned with the partition plate 211 of the housing 21. As a result, a first air port 24 is defined between the partition plate 211 and the protrusion plate 231.

The draining structure 232 is substantially an inclined plate extended from the protrusion plate 231 toward the water-repellent structure 214. The draining structure 232, the inner surface of the housing 21, the partition plate 211 and the protrusion plate 231 cooperatively form a water-repellent chamber 25. In some embodiments, the water-repellent structure 214 includes tilt plates 212 and 213, which are parallel with each other. A second air port 215 is defined between the tilt plate 212 and the inner surface of the housing 21. Another second air port 215 is defined between the tilt plate 212 and the tilt plate 213. A draining port 216 is defined between the tilt plate 213 and the draining structure 232. By means of the water-repellent structure 214 and the draining structure 232, air flow is pumped by a heat-dissipating fan (not shown) mounted in the fan receiving slot 22. Subsequently, the pumped air flow is inputted into the water-repellent chamber 25 through the first air port 24 and then outputted from the second air ports 215. Alternatively, the pumped air flow is inputted into the water-repellent chamber 25 through the second air ports 215 and then outputted from the first air port 24. As a result, the heat generated from the internal electronic components of the electronic device 2 can be actively dissipated away.

Incidentally, water or fluid may be spread on the tilt plates 212 and 213. Since the tilt plates 212 and 213 are inclined with respect to the inner surface of the housing 21, most water or fluid will drop down to the outside of the housing 21 along the tilt plates 212 and 213, but only small amount of water or fluid may be splashed into the water-repellent chamber 25. Even if some water or fluid is splashed into the water-repellent chamber 25 through the second air ports 215 and/or the draining port 216, the partition plate 211 and the protrusion plate 231 may hinder the water or fluid from entering other regions of the electronic device 2. In addition, the water or fluid which is splashed into the water-repellent chamber 25 will drop down on the draining structure 232 by gravity and then flow down to the outside of the housing 21 along the slant surface of the draining structure 232 and through the draining port 216. As a consequence, the water-repellent structure 214 and the draining structure 232 are advantageous of protecting the electronic components of the electronic device 2 from contacting with water.

Referring to FIG. 2(b), the electronic device of FIG. 2(a) is turned over such that the rear surface faces upward. Likewise, if water or fluid is incidentally or carelessly splashed into the water-repellent chamber 25 through the second air ports 215 and/or the draining port 216, the partition plate 211 and the protrusion plate 231 may hinder the water or fluid from entering other regions of the electronic device 2. For discharging the water or fluid, the inner surface 217 of the housing 21 is substantially a slant surface. Under this circumstance, the water or fluid which is splashed into the water-repellent chamber 25 will drop down on the slant surface 217 by gravity and then flow down to the outside of the housing 21 along the slant surface 217 and through the second air port 215 between the tilt plate 212 and the slant surface 217. As a consequence, the water-repellent structure 214 and the draining structure 232 are advantageous of protecting the electronic components of the electronic device 2 from contacting with water. Furthermore, the pumped air flow may be inputted into/outputted from the water-repellent chamber 25 through the second air ports 215 and the draining port 216, so that the heat generated from the internal electronic components of the electronic device 2 will be actively dissipated away.

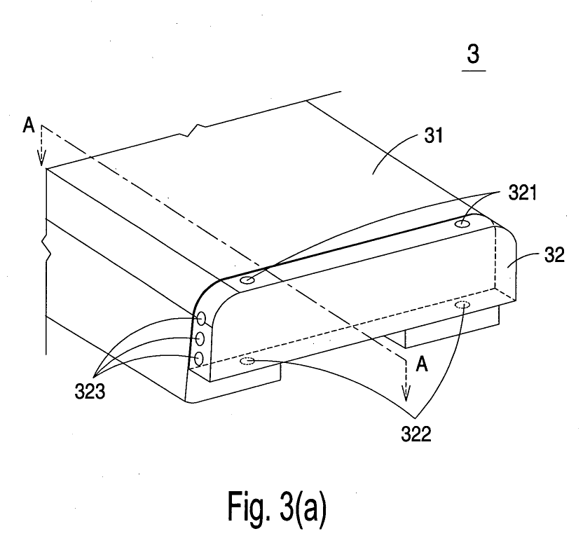

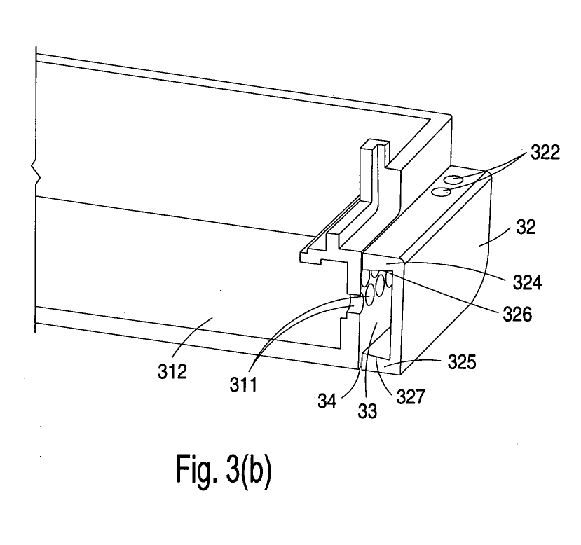

Referring to FIG. 3(a), a perspective view of an electronic device having a water-repellent structure and a draining structure according to a second preferred embodiment is schematically shown. FIG. 3(b) is an upside-down sectional view of the electronic device of FIG. 3(a) taken at the sectioning plane and in the direction indicated by line A-A.

As shown in FIG. 3(a), the electronic device 3 includes a housing 31 and a water-repellent structure 32. As shown in FIG. 3(b), plural first air ports 311 are formed in a side plate of the housing 31 and faces to the water-repellent structure 32. A receptacle 312 is defined by the housing 31 for accommodating a circuit board (not shown) therein.

The water-repellent structure 32 is substantially a cover structure. The water-repellent structure 32 includes one or more first draining ports 321, one or more second draining ports 322 and one or more second air ports 323. The first draining ports 321 and the second draining ports 322 are disposed on a first side plate and a second side plate of the water-repellent structure 32, respectively, wherein the first side plate is opposed to the second side plate. The second air ports 323 are disposed at a third side plate of the water-repellent structure 32. Moreover, the first side plate and the second side plate further include a first draining structure 325 and a second draining structure 324, respectively. The first draining structure 325 and the second draining structure 324 include a first slant surface 327 and a second slant surface 326, respectively. As a consequence, the water or fluid which is splashed into the water-repellent chamber 33 may drop down on either the first slant surface 326 or the second slant surface 327 and flow outside of the water-repellent structure 32 along the slant surface 326 or 327 and through the draining ports 322 or 321.

As shown in FIGS. 3(a) and 3(b), the cover structure 32 is connected to the housing 31. A water-repellent chamber 33 is defined by the cover structure 32 and the housing 31. Moreover, a gap 34 is formed between the first side plate of the cover structure 32 and the housing 31. Under this circumstance, air flow pumped by a heat-dissipating fan (not shown) within the housing 31 may be either transferred from the first air ports 311 to the second air ports 323 and the gap 34, or transferred from the second air ports 323 and the gap 34 to the first air ports 311. As a result, the heat generated from the internal electronic components of the electronic device 3 can be actively dissipated away.

Please refer to FIGS. 3(a) and 3(b) again. Incidentally, water or fluid may be spread on the electronic device 3. Since most water or fluid is hindered by the cover structure 32 and the housing 31, only small amount of water or fluid may be splashed into the water-repellent chamber 33. Even if some water or fluid is splashed into the water-repellent chamber 33 through the first draining ports 321, the second air ports 323 and/or the gap 34, the water or fluid will drop down on the second slant surface 326 by gravity and then flow down to the outside of the housing 31 along the second slant surface 326 of the second draining structure 324 and through the second draining port 322. As a consequence, the water-repellent structure and the draining structure are advantageous of protecting the electronic components of the electronic device 3 from contacting with water.

Referring to FIG. 3(b), the electronic device of FIG. 3(a) is turned over such that the rear surface faces upward. Likewise, if water or fluid is incidentally or carelessly spread on the electronic device 3, most water or fluid is hindered by the cover structure 32 and the housing 31, but only small amount of water or fluid may be splashed into the water-repellent chamber 33. If some water or fluid is incidentally or carelessly splashed into the water-repellent chamber 33 through the second draining ports 322, the water or fluid will drop down on the first slant surface 327 by gravity and then flow down to the outside of the housing 31 along the first slant surface 327 of the first draining structure 325 and through the first draining port 321 and the gap 34. As a consequence, the water-repellent structure and the draining structure are advantageous of protecting the electronic components of the electronic device 3 from contacting with water.

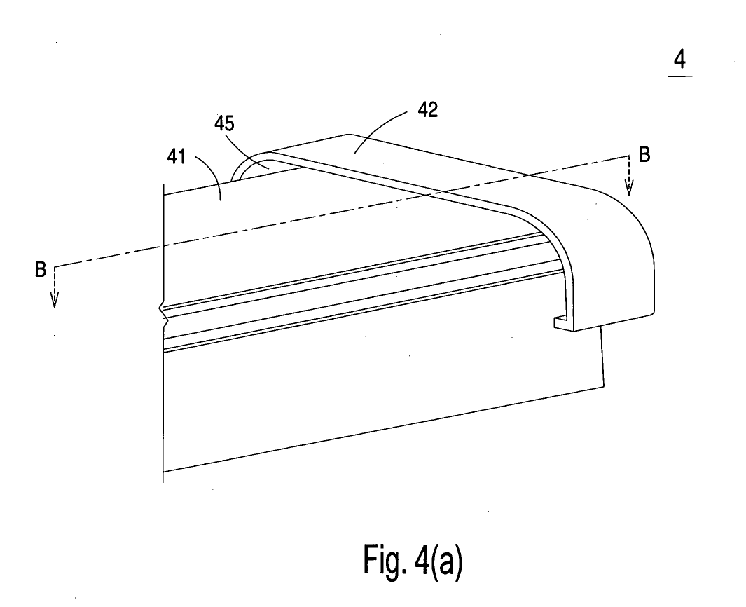

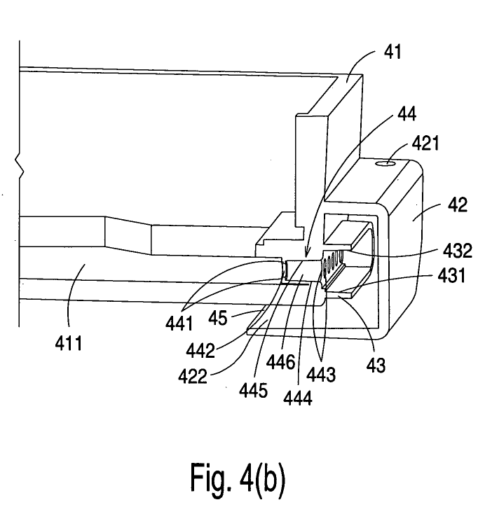

Referring to FIG. 4(a), a perspective view of an electronic device having a water-repellent structure and a draining structure according to a third preferred embodiment is schematically shown. FIG. 4(b) is an upside-down sectional view of the electronic device of FIG. 4(a) taken at the sectioning plane and in the direction indicated by line B-B.

As shown in FIG. 4(a), the electronic device 4 includes a housing 41, a cover member 42, a ring-shaped structure 43 and a water-repellent structure 44. As shown in FIG. 4(b), a receptacle 411 is defined by the housing 41 for accommodating a circuit board (not shown) therein. The water-repellent structure 44 includes plural cylindrical elements. Each cylindrical element includes a baffle 441, an air port 442, a draining port 443 and a water-repellent chamber 446. The water-repellent chamber 446 is defined between the air port 442 and the draining port 443. The cylindrical element is tapered toward the air port 442 such that the inner wall of the cylindrical element has a first slant surface 445 and a second slant surface 444 for facilitating draining the water or liquid which is splashed into the water-repellent chamber 446. The slant surfaces 444 and 445 are referred as a draining structure. Even if some water or fluid is splashed into the water-repellent chamber 446, the baffle 441 may hinder the water or fluid from entering other regions of the electronic device 4 and the water or fluid which is splashed into the water-repellent chamber 446 flows down to the outside of the housing 41 along the slant surface 444 or 445 and through the draining port 443. As a consequence, the water-repellent structure and the draining structure are advantageous of protecting the electronic components of the electronic device 4 from contacting with water.

The ring-shaped structure 43 is protruded from a surface of the housing 41 and encloses the draining ports 443 of the cylindrical elements. The ring-shaped structure 43 may partially hinder the water or fluid from introducing into the water-repellent chambers 446. The ring-shaped structure 43 is tapered toward the housing 41 such that the inner wall of the ring-shaped structure 43 has a first slant surface 431 and a second slant surface 432 for facilitating draining the water or liquid which is splashed into the inner space of the ring-shaped structure 43.

As shown in FIGS. 4(a) and 4(b), a first side plate of the cover member 42 is connected to the housing 41 by using for example an ultrasonic welding operation or other fastening means. A second side plate of the cover member 42 partially encloses the upper surface of the housing 41 such that a gap 45 is formed between the cover member 42 and the housing 41. Under this circumstance, air flow pumped by a heat-dissipating fan (not shown) within the housing 41 may be either transferred from the air ports 442 to the gap 45, or transferred from the gap 45 to the air ports 442. As a result, the heat generated from the internal electronic components of the electronic device 4 can be actively dissipated away. Moreover, the first side plate of the cover member 42 has one or more draining ports 421, and the second side plate of the cover member 42 has a slant surface 422. The draining ports 421 and the slant surface 422 may facilitate draining the water or liquid which is splashed into the cover member 42.

Please refer to FIG. 4(a) again. Incidentally, water or fluid may be spread on the electronic device 4. Since most water or fluid is hindered by the cover member 42 and the housing 41, only small amount of water or fluid may be splashed into the inner space of the cover member 42 through the gap 45. The water or fluid which is splashed into the inner space of the cover member 42 is hindered by the ring-shaped structure 43 and partially drops down on the first side plate of the cover member 42. Even if some water or fluid is splashed into the water-repellent chamber 446, the baffle 441 may hinder the water or fluid from entering other regions of the electronic device 4 and the water or fluid which is splashed into the water-repellent chamber 446 flows down to the inner space of the ring-shaped structure 43 along the slant surface 445 and through the draining port 443. The second slant surface 432 may facilitate guiding the fluid to drop down on the first side plate of the cover member 42 and then discharged outside the cover member 42 through the draining ports 421. As a consequence, the water-repellent structure and the draining structure are advantageous of protecting the electronic components of the electronic device 4 from contacting with water.

Referring to FIG. 4(b), the electronic device of FIG. 4(a) is turned over such that the rear surface faces upward. If water or fluid is incidentally or carelessly spread on the electronic device 4, most water or fluid is hindered by the cover member 42 and the housing 41, but only small amount of water or fluid may be splashed into the inner space of the cover member 42 through the draining ports 421. The water or fluid which is splashed into the inner space of the cover member 42 is hindered by the ring-shaped structure 43 and partially drops down on the second side plate of the cover member 42. Even if some water or fluid is splashed into the water-repellent chamber 446, the baffle 441 may hinder the water or fluid from entering other regions of the electronic device 4 and the water or fluid which is splashed into the water-repellent chamber 446 flows down to the inner space of the ring-shaped structure 43 along the slant surface 444 and through the draining port 443. The first slant surface 431 may facilitate guiding the fluid to drop down on the second side plate of the cover member 42. The slant surface 422 of the second side plate of the cover member 42 may facilitate guiding the fluid outside the cover member 42 through the gaps 45. As a consequence, the water-repellent structure and the draining structure are advantageous of protecting the electronic components of the electronic device 4 from contacting with water.

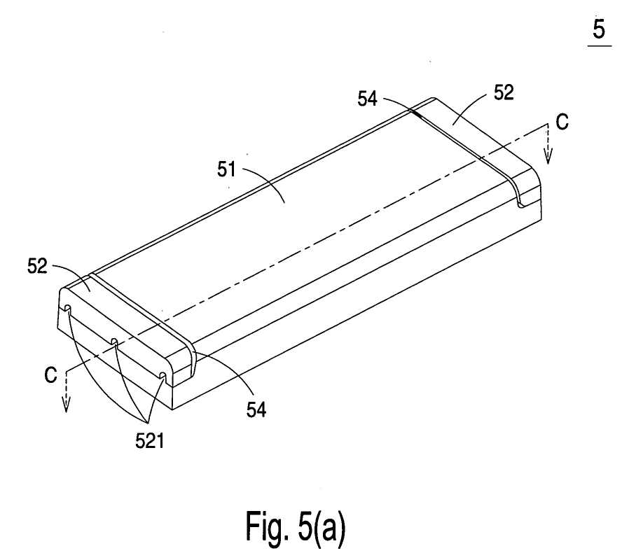

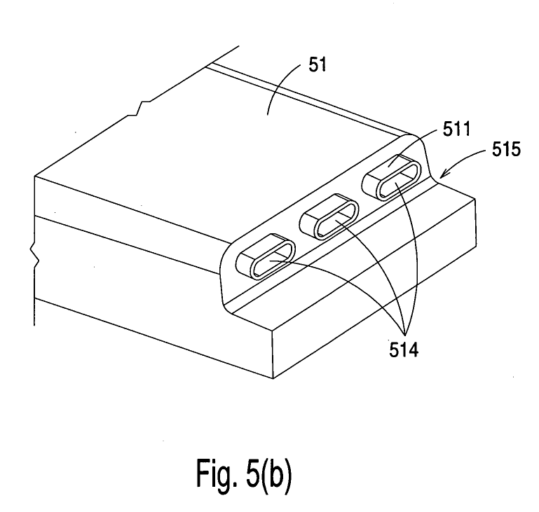

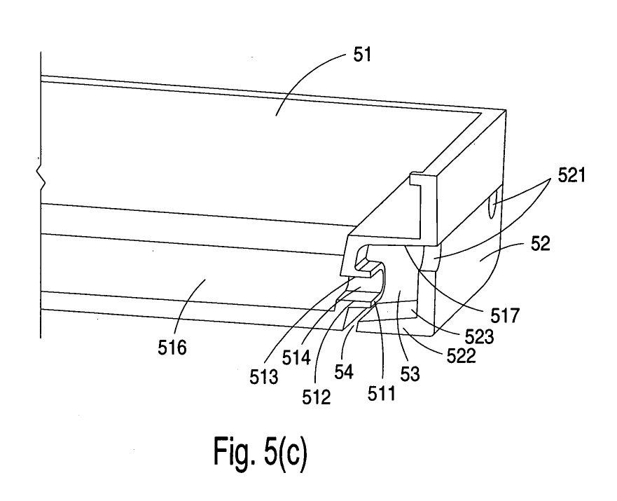

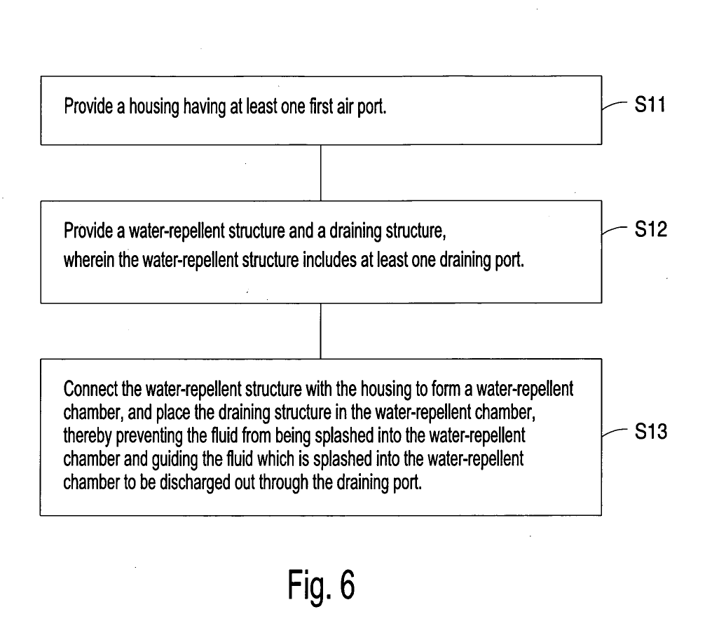

Referring to FIG. 5(a), a perspective view of an electronic device having a water-repellent structure and a draining structure according to a third preferred embodiment is schematically shown. FIG. 5(b) is a partially enlarged view of the electronic device of FIG. 5(a). FIG. 5(c) is an upside-down sectional view of the electronic device of FIG. 5(a) taken at the sectioning plane and in the direction indicated by line C-C.

As shown in FIG. 5(a), the electronic device 5 includes a housing 51 and a water-repellent structure 52. As shown in FIGS. 5(b) and 5(c), the housing 51 includes plural protrusion ring 511, plural air ports 514 and two indentation portions 515 at bilateral sides thereof. The protrusion rings 511 are protruded from the bilateral sides of the housing 51 and confined within the indentation portions 515. The protrusion rings 511 also enclose the air ports 514. The protrusion ring 511 is tapered toward the housing 51 such that the inner wall of the protrusion ring 511 has slant surfaces 512 and 513 for facilitating draining the water or liquid which is splashed into the indentation portions 515. A receptacle 516 is defined by the inner wall of the housing 51 for accommodating a circuit board (not shown) therein. The receptacle 516 is communicated with the air ports 514. Moreover, the indentation portions 515 have slant surfaces 517.

Please refer to FIGS. 5(a), 5(b) and 5(c) again. The water-repellent structure 52 includes two cover structures (hereinafter cover structure is indicated by reference numeral 52), which are connected to the housing 51 and shelter the indentation portions 515. These two cover structures 52 and the indentation portions 515 cooperatively form water-repellent chambers 53. A first side plate of the cover structure 52 includes a draining structure 522, which has a slant surface 523 for facilitating draining the water or liquid which is splashed into the water-repellent chamber 53. In addition, a gap 54 is formed between the first side plate of the cover structure 52 and the housing 51. A second side plate of the cover structure 52 includes plural notches, which are substantially in contact with the housing 51 so as to define plural draining ports 521. Under this circumstance, air flow pumped by a heat-dissipating fan (not shown) within the housing 51 may be either transferred from the air ports 514 to the gap 54, or transferred from the gap 54 to the air ports 514. As a result, the heat generated from the internal electronic components of the electronic device 5 can be actively dissipated away.

Please refer to FIG. 5(a) again. Incidentally, water or fluid may be spread on the electronic device 5. Since most water or fluid is hindered by the cover structures 52 and the housing 51, only small amount of water or fluid may be splashed into the water-repellent chamber 53 through the draining ports 521 and/or the gap 54. The water or fluid which is splashed into the water-repellent chamber 53 is hindered by the protrusion rings 511 and partially drops down on the slant surface 517 of the housing 51. Even if a small amount of water or fluid is splashed into the inner space of the protrusion rings 53, the water or fluid may flow down to the slant surface 517 along the slant surface 513. The slant surface 517 may facilitate guiding the fluid to be discharged outside the cover structure 52 through the draining ports 521. As a consequence, the water-repellent structure and the draining structure are advantageous of protecting the electronic components of the electronic device 5 from contacting with water.

Referring to FIG. 5(c), the electronic device of FIG. 5(a) is turned over such that the rear surface faces upward. Likewise, if water or fluid is incidentally or carelessly spread on the electronic device 5, most water or fluid is hindered by the cover structure 52 and the housing 51, but only small amount of water or fluid may be splashed into the water-repellent chamber 53 through the draining ports 521. The water or fluid which is splashed into the water-repellent chamber 53 will drop down on the slant surface 523 of the draining structure 522 by gravity and then flow down to the outside of the housing 51 along the slant surface 523 and through the gap 54. Even if a small amount of water or fluid is splashed into the inner space of the protrusion rings 511, the water or fluid may flow down to the slant surface 523 along the slant surface 512. The slant surface 523 may facilitate guiding the fluid to be discharged outside the cover structure 52 through the gap 54. As a consequence, the water-repellent structure and the draining structure are advantageous of protecting the electronic components of the electronic device 5 from contacting with water.

In the above embodiments, the electronic devices 2, 3, 4 and 5 are power adapters or power supply apparatuses. The housings 21, 31, 41 and 51 are made of plastics or high thermally conductive material such as metallic material in order to enhance heat-dissipating efficiency. Moreover, the electronic devices of the present invention are portable or applicable in the outdoor environments.

Referring to FIG. 6, a flowchart of the process for fabricating an electronic device having a water-repellent structure and a draining structure is illustrated. First of all, a housing having a first air port is provided (step S11). Then, a water-repellent structure and a draining structure are provided, wherein the water-repellent structure includes at least one draining port (step S12). Afterwards, the water-repellent structure is connected with the housing to form a water-repellent chamber, and the draining structure is placed in the water-repellent chamber, thereby reducing the possibility of splashing the fluid into the water-repellent chamber and guiding the fluid which is splashed into the water-repellent chamber to be discharged out through the draining port (step S13).

From the above description, the water-repellent structure and the draining structure of the present invention are capable of hinder the water or fluid from entering the inner portion of the housing and guiding the fluid which is splashed into said water-repellent chamber to be discharged outside the housing. According to the present invention, the water-repellent structure and the draining structure are advantageous of protecting the electronic components of the electronic device from contacting with water. In addition, since the pumped air flow may be inputted into/outputted from the water-repellent chamber by means of the water-repellent structure and the draining structure, the heat generated from the internal electronic components of the electronic device will be actively dissipated away. As a consequence, the electronic device with the water-repellent structure and the draining structure has extended life and can be operated in many environments.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic device comprising:
a housing having at least one first air port;
a water-repellent structure connected to said housing and including at least one draining port, wherein said water-repellent structure and said housing cooperatively define a water-repellent chamber; and
a draining structure disposed in said water-repellent chamber for preventing the fluid from being splashed into said water-repellent chamber and guiding the fluid which is splashed into said water-repellent chamber to be discharged out through said draining port.

2. The electronic device according to claim 1 being selected from a group consisting of a power adapter and a power supply apparatus.

3. The electronic device according to claim 1 wherein said housing further includes a partition plate extended from an inner surface thereof.

4. The electronic device according to claim 3 further comprising a sheltering member, wherein said sheltering member includes a protrusion plate, which is connected to said draining structure and selectively aligned with said partition plate such that said first air port is defined between said partition plate and said protrusion plate.

5. The electronic device according to claim 1 wherein said water-repellent structure includes plural tilt plates, which are parallel with each other, wherein a plurality of second air ports are defined between every two adjacent tilt plates and between one of said tilt plates and an inner surface of said housing such that an air flow is inputted into and outputted from said water-repellent chamber through said first air port and said second air ports, and said draining port is defined between one of said tilt plates and said draining structure.

6. The electronic device according to claim 5 wherein said inner surface of said housing is a slant surface for guiding the fluid which is splashed into said water-repellent chamber to be discharged outside said housing through said second air ports.

7. The electronic device according to claim 1 wherein said water-repellent structure includes a cover structure having at least a second air port, and a gap is defined between said cover structure and said housing such that air flow is transferred through said at least one first air port, said at least one second air port and said gap.

8. The electronic device according to claim 7 wherein said draining structure include a first side plate and a second side plate of said cover structure, and said at least one draining port includes at least one first draining port in said first side plate and at least one second draining port in said second side plate, wherein said first side plate and said second side plate have first and second slant surfaces for guiding the fluid which is splashed into said water-repellent chamber to be discharged out through said at least one first draining port and said at least one second draining port.

9. The electronic device according to claim 7 wherein said at least one first air port is disposed in a side plate of said housing, and the heat generated from said electronic device is dissipated away said electronic device through said at least one first air port.

10. The electronic device according to claim 1 wherein said water-repellent structure includes at least one cylindrical element, and said cylindrical element has a baffle for partially hindering said fluid from entering an inner portion of said housing.

11. The electronic device according to claim 10 wherein said draining structure is a slant surface on an inner wall of said cylindrical element for guiding the fluid which is splashed into said water-repellent chamber to be discharged out through said at least one draining port.

12. The electronic device according to claim 11 further comprising:
a ring-shaped structure protruded from a surface of said housing and enclosing said at least one draining port for partially hindering said fluid from entering said at least one cylindrical element; and
a cover member enclosing said ring-shaped structure, wherein a first side plate of said cover member is connected to said housing, and a gap is formed between said housing and a second side plate of said cover member, such that an air flow is transferred through said at least one first air port, said at least one draining port and said gap.

13. The electronic device according to claim 1 wherein said housing includes an indentation portion and plural protrusion rings at a lateral side thereof, said protrusion rings being protruded from said lateral side of said housing and confined within said indentation portion.

14. The electronic device according to claim 13 wherein said water-repellent structure includes a cover structure sheltering said indentation portion, wherein said draining structure includes a slant surface of a first side plate of said cover structure, a gap is defined between said cover structure and said housing for guiding the fluid which is splashed into said water-repellent chamber to be discharged out through said gap, a second side plate of said cover structure is connected to said housing and includes said at least one draining port such that air flow is transferred through said at least one first air port and said at least one draining port.

15. A process of fabricating an electronic device, comprising steps of:
providing a housing having at least one first air port;
providing a water-repellent structure and a draining structure, wherein said water-repellent structure includes at least one draining port; and
connecting said water-repellent structure with said housing to form a water-repellent chamber, and placing said draining structure in said water-repellent chamber, thereby preventing the fluid from being splashed into said water-repellent chamber and guiding the fluid which is splashed into said water-repellent chamber to be discharged out through said at least one draining port.

16. The process according to claim 15 wherein said water-repellent structure includes a cover structure having at least one second air port, and a gap is defined between said cover structure and said housing such that air flow is transferred through said at least one first air port, said at least one second air port and said gap.

17. The process according to claim 16 wherein said draining structure include a first side plate and a second side plate of said cover structure, and said at least one draining port includes at least one first draining port in said first side plate and at least one second draining port in said second side plate, wherein said first side plate and said second side plate have first and second slant surfaces for guiding the fluid which is splashed into said water-repellent chamber to be discharged out through said at least one first draining port and said at least one second draining port.

18. The process according to claim 16 wherein said at least one first air port is disposed in a side plate of said housing, and the heat generated from said electronic device is dissipated away said electronic device through said at least one first air port.

19. The process according to claim 15 wherein said housing includes an indentation portion and plural protrusion rings at a lateral side thereof, said protrusion rings being protruded from said lateral side of said housing and confined within said indentation portion.

20. The process according to claim 19 wherein said water-repellent structure includes a cover structure sheltering said indentation portion, wherein said draining structure includes a slant surface of a first side plate of said cover structure, a gap is defined between said cover structure and said housing for guiding the fluid which is splashed into said water-repellent chamber to be discharged out through said gap, a second side plate of said cover structure is connected to said housing and includes said at least one draining port such that air flow is transferred through said at least one first air port and said at least one draining port.
